(19) United States
(12) Patent Application Publication
(10) Pub. No.: US 2014/0262443 A1
(43) Pub. Date: Sep. 18, 2014

(54) HYBRID PATTERNED NANOSTRUCTURE TRANSPARENT CONDUCTORS

(71) Applicant: Cambrios Technologies Corporation, Sunnyvale, CA (US)

(72) Inventor: Paul Mansky, San Francisco, CA (US)

(73) Assignee: CAMBRIOS TECHNOLOGIES CORPORATION, Sunnyvale, CA (US)

(21) Appl. No.: 14/208,536

(22) Filed: Mar. 13, 2014

Related U.S. Application Data
(60) Provisional application No. 61/785,576, filed on Mar. 14, 2013.

(51) Int. Cl. H05K 3/02; H05K 1/11

(52) U.S. Cl. CPC H05K 3/02; H05K 1/11
USPC 174/250; 216/13

(57) ABSTRACT

Disclosed herein are nanostructure patterned transparent conductors and methods of forming such transparent conductors including using a deposition method to form an active area and peripheral area and patterning method to pattern the active area.

### BACKGROUND

1. Technical Field

This invention is related to transparent conductors, methods of manufacturing and patterning the same, and applications thereof.

2. Description of the Related Art

Transparent conductors refer to thin conductive films coated on high-transmittance surfaces or substrates. Transparent conductors may be manufactured to have surface conductivity while maintaining reasonable optical transparency. Such surface conducting transparent conductors are widely used as transparent electrodes in flat liquid crystal displays, touch panels, electroluminescent devices, and thin film photovoltaic cells, as anti-static layers and as electromagnetic wave shielding layers.

Currently, vacuum deposited metal oxides, such as indium tin oxide (ITO), are the industry standard materials to provide optically transparency and electrical conductivity to dielectric surfaces such as glass and polymeric films. However, metal oxide films are fragile and prone to damage during bending or other physical stresses. They also require elevated deposition temperatures and/or high annealing temperatures to achieve high conductivity levels. There also may be issues with the adhesion of metal oxide films to substrates that are prone to adsorbing moisture such as plastic and organic substrates, e.g. polycarbonates. Applications of metal oxide films on flexible substrates are therefore severely limited. In addition, vacuum deposition is a costly process and requires specialized equipment. Moreover, the process of vacuum deposition is not conducive to forming patterns and circuits. This typically results in the need for expensive patterning processes such as photolithography.

Laser patterning can also be used to pattern conducting layers with high resolution (gaps down to about 10-15 um) and excellent low pattern visibility. However conventional laser patterning is a scanning process, whereby the laser beam is scanned over the substrate to form the pattern, and hence the processing time depends on the pattern complexity and extent. Generally speaking, laser patterning is more economically viable the simpler the pattern.

Accordingly, there remains a need in the art to provide transparent conductors having desirable electrical, optical and mechanical properties, in particular, transparent conductors that can be patterned in a low-cost, high-throughput process.

### BRIEF SUMMARY

Transparent conductors based on electrically conductive nanowires in an optically clear matrix or overcoat are described. The transparent conductors are patternable and are suitable as transparent electrodes in a wide variety of devices including, without limitation, display devices (e.g., touch screens, liquid crystal displays, plasma display panels and the like), electroluminescent devices such as OLED devices, and photovoltaic cells. As used herein, “patterning” broadly refers to a process that creates conductive lines or traces and areas or lines between the conductive lines that are of reduced or essentially no conductivity. “Patterning” does not necessarily create any repeating features other than that any two conductive lines be electrically isolated from each other by an insulating region.

In one embodiment, a method of forming a patterned transparent conductor including anisotropic metallic nanowires comprises depositing a transparent conductive layer including anisotropic metallic nanowires on a substrate to form an active area and a peripheral area, the active area including the transparent conductive layer and the peripheral area being non-conductive. The active area is patterned to form first regions having a first conductivity and second regions having a second conductivity less than the first conductivity. In different embodiments, the transparent conductive layer is deposited using sheet coating, web-coating, screen printing, flexographic printing, gravure printing, gravure offset printing, reverse offset printing, inkjet printing, slot die coating, or aerosol spray coating and the active area is patterned by laser patterning or etching.

### BRIEF DESCRIPTION OF THE SEVERAL VIEWS OF THE DRAWINGS

In the drawings, identical reference numbers identify similar elements. The sizes and relative positions of elements in the drawings are not necessarily drawn to scale. For example, the shapes of various elements and angles are not drawn to scale, and some of these elements are arbitrarily enlarged and positioned to improve drawing legibility. Further, the particular shapes of the elements as drawn are not intended to convey any information regarding the actual shape of the particular elements, and they have been solely selected for ease of recognition in the drawings.

FIG. 1 illustrates one embodiment of a transparent conductor including an active area and peripheral area in accordance with the present invention.

FIG. 2 illustrates one embodiment of a transparent conductor including an active area and a peripheral area wherein the active area is patterned in accordance with the present invention.

FIG. 3 is a flow chart showing one embodiment of a method of forming a transparent conductive film into a patterned active area and a peripheral area in accordance with the present invention.

### DETAILED DESCRIPTION

In a device including patterned transparent conductors, such as touch panels and other display devices, photoelectric cells, OLEDs, and other electroluminescent devices, an active area can be distinguished as the area of touch sensitivity in a touch panel, the display area in other display devices, light sensitivity in a photovoltaic cell or area of illumination in an OLED or other electroluminescent device. A peripheral area of such a device can include bus bars which connect the electrodes to the driving IC, and in some cases, antennas.

When laser patterning is used to pattern a continuous conducting layer that encompasses both the active area and peripheral area of a device, patterning must be done not only in the active area of the sensor, but also in the peripheral area, beyond the edge of the active area. This is necessary to isolate the bus bars which connect the electrodes to the driving IC, and in some cases may also be necessary to eliminate unwanted shielding effects on the antennas in the final device. If bus bars are printed, complete removal of all conducting material in the peripheral area by a laser prior to bus bar printing can significantly increase the patterning time and reduce output; in fact this can potentially take more time than defining an electrode pattern in the active area of the sensor. A less time consuming alternative is to use the laser beam only to isolate the bus bars (conductive traces) from each other, however this may take roughly the same amount of time as patterning of the active area, and does not necessarily eliminate shielding effects.

Described herein is a method of forming a transparent conductor wherein the conductive material is deposited onto a substrate in a region corresponding approximately to the size and shape of the active area of the final device, typically a rectangle. Then in a second step, the active area is subdivided into electrically isolated regions (electrodes) by a patterning process, preferably laser patterning, but also, in other embodiments, by mechanical scribing, etching, or other methods. In this way, the amount of laser patterning process time required to form the sensor is greatly reduced, and the cost effectiveness of laser patterning is improved.

The active area of the substrate may be formed by a deposition process, such as, without limitation, sheet coating, web-coating, screen printing, flexographic printing, gravure printing, gravure offset printing, reverse offset printing, inkjet printing, pad, slot die coating, aerosol spray coating. These deposition processes for forming nanostructure transparent conductors are described, for example, in U.S. Pat. Nos. 8,094,247 and 8,018,568; and U.S. patent application Ser. Nos. 13/278,733; 12/389,293; and 12/380,294; each of which is incorporated by reference herein in its entirety.

In one embodiment, the active area is continuously covered with the conducting material, with no pattern. In other embodiments, some patterning may be included in the active area as part of the deposition process. Preferably, any additional patterning done in this step comprises features of 100 μm, 200 μm, or 500 μm or larger.

In the patterning step, a relatively high resolution process is used to subdivide the active area into isolated sub-regions (electrodes). This can be done by laser patterning, mechanical scribing, etching or other method. Preferably, the method used in the patterning step is one which provides very low pattern visibility, and which could also be used solely to pattern the entire sensor if desired, but where patterning time increases with the complexity and extent of the design (particularly if there were a need to pattern the peripheral area of the sensor with the higher resolution process). Laser patterning of anisotropic metallic nanostructure transparent conductors is disclosed, for example, in “Laser Patterning of Silver Nanowire”, T. Pothoven, Information Display, 9/12, pp. 20-24, which is incorporated herein by reference in its entirety. Etch low visibility etch patterning of metallic nanostructure transparent conductors is disclosed in U.S. Pat. No. 8,018,568 which has been incorporated by reference herein.

Because no material needs to be removed outside the active area of the device (e.g. in the peripheral area), the second patterning step can be executed in a shorter time, when combined with the first step, than would be possible if only the second patterning method was used. Advantageously, depending on the cost and speed of the deposition and patterning processes, as well as the sensor design, fully functional devices with relatively low visibility patterns may be produced in a relatively cost effective manner.

FIG. 1 shows a transparent conductor 10 having a substrate 12 that has the dimensions of a touch sensor or other device using a patterned, transparent conductive layer. Conductor 10 includes an active area 14 and a peripheral area 16. Active area 14 includes a transparent conductive film including anisotropic metallic nanostructures. No conductive film has been deposited in the peripheral area 16. FIG. 2 shows transparent conductor 10 wherein the active area 14 has been laser patterned to form conductive lines 18 having areas of different conductivity therebetween. The areas between the conductive lines may have a reduced conductivity or they may rendered non-conductive. As used herein, “non-conductive” refers to a surface resistivity of at least 10⁶Ω/□. In some embodiments, the difference in conductivity between the conductive lines 18 and the areas between the conductive lines can be from 500Ω/□ to 10⁵Ω/□ or greater. In one embodiment, the area of the active area is from 10% to 95% of the sum of the area of the peripheral area and the area of the active area.

FIG. 3 is a flow chart illustrating one embodiment of a method 110 of forming a transparent conductor in accordance with the present invention. In step 112, a conductive layer including anisotropic metallic nanostructures is deposited onto a substrate to form an active area and peripheral area of a device. In different embodiments, sheet coating, web-coating, screen printing, flexographic printing, gravure printing, gravure offset printing, reverse offset printing, inkjet printing, pad, slot die coating, aerosol spray coating are use to deposit the conductive coating material in only the active area of a substrate. In one embodiment, step 112 is carried out by roll-to-roll deposition onto a moving substrate web. Step 112 can be followed by an optional drying step 114 and optional calendaring step 116. In one embodiment, steps 114 and 116 are carried out by roll-to-roll processing stations. In step 118, the active area is patterned into conductive areas having areas of reduced or no conductivity therebetween. The patterning of step 118 may be carried out with one or more laser beams or mechanical scribes. In one embodiment, the web moves past the patterning station in a roll-to-roll process. In one embodiment, the laser beams or scribes are stationary and evenly spaced in the roll-to-roll process and continually act on the web, such that each rectangle is divided into sub-rectangles. In other embodiments, the beam or scribe may also be moved during step 118, and engaged/disengaged with the substrate, to form more complex patterns.

In another embodiment active areas of multiple devices are formed in a roll to roll process on a substrate web, while the patterning step is performed after the web has been cut up into individual sheets (sheet process). In yet another embodiment the deposition and patterning steps are performed on individual sheets of the substrate

In all of the above embodiments, additional steps may comprise forming bus bars in electrical contact with the individual electrodes, and application of additional layers on top of the electrodes, such as dielectric/insulating layers or additional conductive layers.

### Metal Nanostructures

As used herein, “anisotropic metal nanostructures” generally refer to electrically conductive nano-sized structures, at least one dimension of which (i.e., width or diameter) is less than 500 nm; more typically, less than 100 nm or 50 nm. In various embodiments, the width or diameter of the nanostructures are in the range of 10 to 40 nm, 20 to 40 nm, 5 to 20 nm, 10 to 30 nm, 40 to 60 nm, 50 to 70 nm.

One way for defining the geometry of a given nanostructure is by its “aspect ratio,” which refers to the ratio of the length and the width (or diameter) of the nanostructure. In preferred embodiments, the nanostructures are anisotropically shaped (i.e. aspect ratio≠1). The anisotropic nanostructure typically has a longitudinal axis along its length. Exemplary anisotropic nanostructures include nanowires (solid nanostructures having aspect ratio of at least 10, and more typically, at least 50), nanorod (solid nanostructures having aspect ratio of less than 10) and nanotubes (hollow nanostructures).

Lengthwise, anisotropic nanostructures (e.g., nanowires) are more than 500 nm, or more than 1 μm, or more than 10 μm in length. In various embodiments, the lengths of the nanostructures are in the range of 5 to 30 μm, or in the range of 15 to 50 μm, 25 to 75 μm, 30 to 60 μm, 40 to 80 μm, or 50 to 100 μm.

Metal nanostructures are typically a metallic material, including elemental metal (e.g., transition metals) or a metal compound (e.g., metal oxide). The metallic material can also be a bimetallic material or a metal alloy, which comprises two or more types of metal. Suitable metals include, but are not limited to, silver, gold, copper, nickel, gold-plated silver, platinum and palladium. It should be noted that although the present disclosure describes primarily nanowires (e.g., silver nanowires), any nanostructures within the above definition can be equally employed.

Typically, metal nanostructures are metal nanowires that have aspect ratios in the range of 10 to 100,000. Larger aspect ratios can be favored for obtaining a transparent conductor layer since they may enable more efficient conductive networks to be formed while permitting lower overall density of wires for a high transparency. In other words, when conductive nanowires with high aspect ratios are used, the density of the nanowires that achieves a conductive network can be low enough that the conductive network is substantially transparent.

Metal nanowires can be prepared by known methods in the art. In particular, silver nanowires can be synthesized through solution-phase reduction of a silver salt (e.g., silver nitrate) in the presence of a polyol (e.g., ethylene glycol) and polyvinyl pyrrolidone). Large-scale production of silver nanowires of uniform size can be prepared and purified according to the methods described in U.S. Published Application Nos. 2008/0210052, 2011/0024159, 2011/0045272, and 2011/0048170, all in the name of Cambrios Technologies Corporation, the assignee of the present disclosure.

### Conductive Network

A conductive network refers to a layer of interconnecting metal nanostructures (e.g., nanowires) that provide the electrically conductive media of a transparent conductor. Since electrical conductivity is achieved by electrical charge percolating from one metal nanostructure to another, sufficient metal nanowires must be present in the conductive network to reach an electrical percolation threshold and become conductive. The surface conductivity of the conductive network is inversely proportional to its surface resistivity, sometimes referred to as sheet resistance, which can be measured by known methods in the art. As used herein, “electrically conductive” or simply “conductive” corresponds to a surface resistivity of no more than 10⁴Ω/□, or more typically, no more than 1,000Ω/□, or more typically no more than 500Ω/□, or more typically no more than 200Ω/□. The surface resistivity depends on factors such as the aspect ratio, the degree of alignment, degree of agglomeration and the resistivity of the interconnecting metal nanostructures.

In certain embodiments, the metal nanostructures may form a conductive network on a substrate without a binder. In other embodiments, a binder may be present that facilitates adhesion of the nanostructures to the substrate. Suitable binders include optically clear polymers including, without limitation: polyacrylics such as polymethacrylates (e.g., poly(methyl methacrylate)), polyacrylates and polyacrylonitriles, polyvinyl alcohols, polyesters (e.g., polyethylene terephthalate (PET), polyester naphthalate, and polycarbonates), polymers with a high degree of aromaticity such as phenolics or cresol-formaldehyde (Novolacs®), polystyrenes, polyvinyltoluene, polyvinylxylene, polyimides, polyamides, polyamideimides, polyetherimides, polysulfides, polysulfones, polyphenylenes, and polyphenyl ethers, polyurethane (PU), epoxy, polyolefins (e.g. polypropylene, polymethylpentene, and cyclic olefins), acrylonitrile-butadiene-styrene copolymer (ABS), cellulosics, silicones and other silicon-containing polymers (e.g. polysilsesquioxanes and polysilanes), polyvinylchloride (PVC), polyacetates, polynorbornenes, synthetic rubbers (e.g., EPR, SBR, EPDM), and fluoropolymers (e.g., polyvinylidene fluoride, polytetrafluoroethylene (TFE) or polyhexafluoropropylene), copolymers of fluoro-olefin and hydrocarbon olefin (e.g., Lumiflon®), and amorphous fluorocarbon polymers or copolymers (e.g., CYTOP® by Asahi Glass Co., or Teflon® AF by Du Pont).

“Substrate” refers to a non-conductive material onto which the metal nanostructure is coated or laminated. The substrate can be rigid or flexible. The substrate can be clear or opaque. Suitable rigid substrates include, for example, glass, polycarbonates, acrylics, and the like. Suitable flexible substrates include, but are not limited to: polyesters (e.g., polyethylene terephthalate (PET), polyester naphthalate, and polycarbonate), polyolefins (e.g., linear, branched, and cyclic polyolefins), polyvinyls (e.g., polyvinyl chloride, polyvinylidene chloride, polyvinyl acetals, polystyrene, polyacrylates, and the like), cellulose ester bases (e.g., cellulose triacetate, cellulose acetate), polysulphones such as polyethersulphone, polyimides, silicones and other conventional polymeric films. Additional examples of suitable substrates can be found in, e.g., U.S. Pat. No. 6,975,067.

Typically, the optical transparence or clarity of the transparent conductor (i.e., a conductive network on a non-conductive substrate) can be quantitatively defined by parameters including light transmission and haze. “Light transmission” (or “light transmissivity”) refers to the percentage of an incident light transmitted through a medium. In various embodiments, the light transmission of the conductive layer is at least 80% and can be as high as 98%. Performance-enhancing layers, such as an adhesive layer, anti-reflective layer, or anti-glare layer, may further contribute to reducing the overall light transmission of the transparent conductor. In various embodiments, the light transmission (T %) of the transparent conductors can be at least 50%, at least 60%, at least 70%, or at least 80% and may be as high as at least 91% to 92%, or at least 95%.

Haze (H %) is a measure of light scattering. It refers to the percentage of the quantity of light separated from the incident light and scattered during transmission. Unlike light transmission, which is largely a property of the medium, haze is often a production concern and is typically caused by surface roughness and embedded particles or compositional heterogeneities in the medium. Typically, haze of a conductive film can be significantly impacted by the diameters of the nanostructures. Nanostructures of larger diameters (e.g., thicker nanowires) are typically associated with a higher haze. In various embodiments, the haze of the transparent conductor is no more than 10%, no more than 8%, or no more than 5% and may be as low as no more than 2%, no more than 1%, or no more than 0.5%, or no more than 0.25%.

### Coating Composition

The patterned transparent conductors according to the present disclosure are prepared by coating a nanostructure-containing coating composition on a non-conductive substrate. To form a coating composition, the metal nanowires are typically dispersed in a volatile liquid to facilitate the coating process. It is understood that, as used herein, any non-corrosive volatile liquid in which the metal nanowires can form a stable dispersion can be used. Preferably, the metal nanowires are dispersed in water, an alcohol, a ketone, ethers, hydrocarbons or an aromatic solvent (benzene, toluene, xylene, etc.). More preferably, the liquid is volatile, having a boiling point of no more than 200° C., no more than 150° C., or no more than 100° C.

In addition, the metal nanowire dispersion may contain additives and binders to control viscosity, corrosion, adhesion, and nanowire dispersion. Examples of suitable additives and binders include, but are not limited to, carboxy methyl cellulose (CMC), 2-hydroxy ethyl cellulose (HEC), hydroxy propyl methyl cellulose (HPMC), methyl cellulose (MC), poly vinyl alcohol (PVA), tripropylene glycol (TPG), and xanthan gum (XG), and surfactants such as ethoxylates, alkoxylates, ethylene oxide and propylene oxide and their copolymers, sulfonates, sulfates, disulfonate salts, sulfosuccinates, phosphate esters, and fluorosurfactants (e.g., Zonyl® by DuPont).

In one example, a nanowire dispersion, or “ink” includes, by weight, from 0.0025% to 0.1% surfactant (e.g., a preferred range is from 0.0025% to 0.05% for Zonyl® FSO-100), from 0.02% to 4% viscosity modifier (e.g., a preferred range is 0.02% to 0.5% for HPMC), from 94.5% to 99.0% solvent and from 0.05% to 1.4% metal nanowires. Representative examples of suitable surfactants include Zonyl FSN, Zonyl® FSO, Zonyl® FSH, Triton (x100, x114, x45), Dynol (604, 607), n-Dodecyl b-D-maltoside and Novek. Examples of suitable viscosity modifiers include hydroxypropyl methyl cellulose (HPMC), methyl cellulose, xanthan gum, polyvinyl alcohol, carboxy methyl cellulose, and hydroxy ethyl cellulose. Examples of suitable solvents include water and isopropanol.

The nanowire concentration in the dispersion can affect or determine parameters such as thickness, conductivity (including surface conductivity), optical transparency, and mechanical properties of the nanowire network layer. The percentage of the solvent can be adjusted to provide a desired concentration of the nanowires in the dispersion. In preferred embodiments the relative ratios of the other ingredients, however, can remain the same. In particular, the ratio of the surfactant to the viscosity modifier is preferably in the range of about 80 to about 0.01; the ratio of the viscosity modifier to the metal nanowires is preferably in the range of about 5 to about 0.000625; and the ratio of the metal nanowires to the surfactant is preferably in the range of about 560 to about 5. The ratios of components of the dispersion may be modified depending on the substrate and the method of application used. The preferred viscosity range for the nanowire dispersion is between about 1 and 100 cP.

Following the coating, the volatile liquid is removed by evaporation. The evaporation can be accelerated by heating (e.g., baking). The resulting nanowire network layer may require post-treatment to render it electrically conductive. This post-treatment can be a process Step involving exposure to heat, plasma, corona discharge, UV-ozone, or pressure as described below.

Examples of suitable coating compositions are described in U.S. Published Application Nos. 2007/0074316, 2009/0283304, 2009/0223703, and 2012/0104374, all in the name of Cambrios Technologies Corporation, the assignee of the present disclosure.

The coating composition is coated on a substrate by, for example, sheet coating, web-coating, printing, and lamination, to provide a transparent conductor. Additional information for fabricating transparent conductors from conductive nanostructures is disclosed in, for example, U.S. Published Patent Application No. 2008/0143906, and 2007/0074316, in the name of Cambrios Technologies Corporation.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method of forming a patterned transparent conductor including anisotropic metallic nanostructures comprising:
depositing a transparent conductive layer including anisotropic metallic nanostructures on a substrate to form an active area and a peripheral area, the active area including the transparent conductive layer and the peripheral area being non-conductive; and
patterning the active area to form first regions having a first conductivity and second regions having a second conductivity less than the first conductivity.

2. The method of claim 1 wherein depositing a transparent conductive layer includes a deposition method selected from the group consisting of; sheet coating, web-coating, screen printing, flexographic printing, gravure printing, gravure offset printing, reverse offset printing, inkjet printing, slot die coating, and aerosol spray coating.

3. The method of claim 1 wherein the active area is patterned by laser patterning or etching.

4. The method of any of claim 1 wherein the area of the active area is from 10% to 95% of the sum of the area of the peripheral area and the area of the active area.

5. The method of any of claim 1 wherein the second areas are non-conductive.

6. The method of any of claim 1 wherein the patterned transparent conductor is formed using a roll-to-roll process.

7. A touch screen, photovoltaic cell, or electroluminescent device including the transparent conductor of any of claim 1.
